(19) United States
(12) Patent Application Publication
(10) Pub. No.: US 2014/0268994 A1
(43) Pub. Date: Sep. 18, 2014

(54) Write-Time Based Memristive Physical Unclonable Function

(71) Applicant: UNITED STATES OF AMERICA AS REPRESENTED BY THE SECRETARY OF THE AIR FORCE, (US)

(72) Inventors: GARRETT ROSE, CLINTON, NY (US); NATHAN MCDONALD, ROME, NY (US); LOK-KWONG YAN, ORISKANY, NY (US); BRYANT WYSOCKI, TABERG, NY (US)

(21) Appl. No.: 13/868,529

(22) Filed: Apr. 23, 2013

Related U.S. Application Data
(60) Provisional application No. 61/851,572, filed on Mar. 14, 2013.

(51) Int. Cl. G11C 13/00

(52) U.S. Cl. CPC G11C 13/0059
USPC 365/148

(57) ABSTRACT

A physical unclonable function (PUF) device consisting of a hybrid CMOS-memristor circuit that leverages variations in the required write-time of a memristor. Variations in the time required to write, or SET, a memristor from a high to low resistance state arise from variability in physical parameters such as the memristor thickness. When applying a SET voltage across the memristor for the nominal minimum SET time, variability leads to a situation where the memristor will actually SET to the low resistance state only 50% of the time. When the device does not SET it will remain in the high resistance state. Since the to resistance state of the memristor corresponds to reading either a logic 1 or logic 0 on the output of the circuit, the write-time based memristive PUF produces a digital signature directly corresponding to the fabrication process-induced physical variations of an integrated circuit.

### PRIORITY CLAIM UNDER 35 U.S.C. §119(e)

This patent application claims the priority benefit of the filing date of provisional application Ser. No. 61/851,572 having been filed in the United States Patent and to Trademark Office on Mar. 14, 2013 and now incorporated by reference herein.

### STATEMENT OF GOVERNMENT INTEREST

The invention described herein may be manufactured and used by or for the Government for governmental purposes without the payment of any royalty thereon.

### BACKGROUND OF THE INVENTION

Electronic counterfeiting and recirculation is a growing problem. Analysts estimate that nearly 2% of global technology products are likely counterfeits totaling over $7.5 billion in yearly losses to the U.S. semiconductor industry as a whole. Approximately over one million suspect parts are associated with the U.S. DoD supply chain alone [1]. Much of this stems from the lack of a secure, unique identifier to verify the authenticity and trust of electronic products to which researchers have proposed Physical Unclonable Functions (PUFs) as a solution.

PUFs [2-4] are functions that map intrinsic properties of hardware devices (e.g. process variability) into usable and unique “bits” of information. These unique bits have been used as security primitives in several ways, including as unique identifiers, as secret keys, and as pseudo-random bit generator seeds. While previous researchers have focused on designing PUFs that take advantage of measurable/quantifiable characteristics in CMOS devices (such as propagation delay due to process variability), ongoing advancements in the synthesis, manipulation, and testing of materials on a control level approaching atomic scales opens up possibilities of identifying PUF sources in nano-scale devices. In recent years, a wide variety of nano-devices have been successfully realized. Examples of these emerging nano-devices include metal-oxide memristors, phase change devices, spin-torque transfer devices, carbon nanotubes, graphene, and quantum-dots. Memristors are particularly well suited for PUF implementation due to their controlled sensitivity to process variation and relative compatibility with CMOS fabrication standards.

### OBJECTS AND SUMMARY OF THE INVENTION

Principle aspects of the invention include both a circuit and a method for implementing a Physical Unclonable Function (PUF) based on memristive switching devices.

An object of the present invention is to provide an apparatus that is capable of generating an unclonable function for producing a truly random numeric output.

Another object of the present invention is to generate truly random numeric outputs based on the process variations inherent in electronic device fabrication.

Yet another object of the present invention is to generate truly random logical outputs based on memristor high resistance-to-low resistance switching characteristics.

Briefly stated, the present invention is an electronic device consisting of a hybrid CMOS-memristor circuit that leverages variations in the required write-time of a memristor in the implementation of a CMOS-memristor physical unclonable function (PUF). As with any PUF, the circuit relies on process variations to produce a signature that is unique to the specific integrated circuit (IC) on which the PUF is fabricated. Thus, the write-time based memristive PUF (see FIG. 1) is useful for mitigating a variety of potential hardware security concerns such as IC piracy and counterfeiting. This particular invention relies on variations in the time required to write, or SET, a memristor from a high to low resistance state that arises from variability in physical parameters such as the memristor thickness. When applying a SET voltage across the memristor for the nominal minimum SET time, variability leads to a situation where the memristor will actually SET to the low resistance state only 50% of the time. When the device does not SET it will remain in the high resistance state. Since the resistance state of the memristor corresponds to reading either a logic 1 or logic 0 on the output of the circuit, the write-time based memristive PUF produces a digital signature directly corresponding to the physical variations of the IC on which it is fabricated.

### REFERENCES

[1] “Inquiry into Counterfeit Electronic Parts in the Department of Defense Supply Chain,” Report 112-167, Committee on Armed Services, 112^{th} Congress, 2^{nd} Session, United States Senate, U.S. Government Printing Office, Washington, D.C., 21 May 2012.
[2] G. E. Suh, C. W. O'Donnell, I. Sachdev, and S. Devadas, “Design and implementation of the AEGIS single-chip secure processor using physical random functions,” Proc. of IEEE/ACM Intl. Conf on Computer Architecture, pp. 25-36, May 2005.
[3] Y. Alkabani and F. Koushanfar, “Active control and digital rights management of integrated circuit IP cores,” Proc. of the IEEE Intl. Conf. on Compilers, Architectures and Synthesis for Embedded Systems, pp. 227-234 (2008)
[4] J. Guajardo, S. Kumar, G.-J. Schrijen, and P. Tuyls, “Physical unclonable functions and public-key crypto for FPGA IP protection,” Proc. of the IEEE Intl. Conf. on Field Programmable Logic and Applications, pp. 189-195 (2007)
[5] L. Goux, J. G. Lisoni, M. Jurczak, D. J. Wouters, L. Courtade, and Ch. Muller, “Coexistence of the bipolar and unipolar resistive-switching modes in NiO cells made by thermal oxidation of Ni layers,” J. Appl. Phys., Vol. 107, No. 2, pp. 024512-024512-7 (2010)
[6] B. D. Briggs, S. M. Bishop, K. D. Leedy, B. Butcher, R. L. Moore, S. W. Novak, and N. C. Cady, “Influence of Copper on the Switching Properties of Hafnium Oxide-Based Resistive Memory,” MRS Proceedings, Vol. 1337 (2011)
[7] A. Sawa, T. Fujii, M. Kawasaki, and Y. Tokura, “Interfaces resistance switching at a few nanometer thick perovskite manganite layers,” Appl. Phys. Lett., Vol. 88, No. 23 pp. 232112-232112-3 (2006)
[8] K. Szot, W. Speier. G. Bihlmayer, and R. Waser, “Switching the electrical resistance of individual dislocations in single crystalline SrTiO3,” Nat. Mat., Vol. 5, pp. 312-320 (2006)
[9] J. C. Scott and L. D. Bozano, “Nonvolatile memory elements based on organic materials.” Adv. Mat., Vol. 19, pp. 1452-1463 (2007)
[10] N. B. Zhitenev. A. Sidorenko, D. M. Tennant, and R. A. Cirelli, “Chemical modification of the electronic conducting states in polymer nanodevices,” Nat. Nanotech. Vol. 2, pp. 237-242.
[11] M. Di Ventra. Y. V. Pershin, L. O. Chua, “Circuit Elements With Memory: Memristors, Memcapacitors, and Meminductors,” Proc. IEEE. Vol. 97, pp. 1717-1724 (2009).
[12] D. B. Strukov, G. S. Snider, D. R. Stewart and R. S. Williams “How we found the Missing Memristor,” Nature, Vol. 453, pp. 80-83 (2008)
[13] J. P. Strachan, D. B. Strukov, J. Borghetti, J. J. Yang, G. Medeiros-Ribeiro, and R. S. Williams, “The switching location of a bipolar memristor: chemical, thermal and structural mapping,” Nanotechnology, Vol. 22, No. 25, 254015 (2011)
[14] G. S. Rose, H. Manem, J. Rajendran, R. Karri, and R. Pino, “Leveraging Memristive Systems in the Constructure of Digital Logic Circuits and Architectures,” Proceedings of the IEEE, Vol. 100, No. 6, June 2012.
[15] Y. Joglekar and S. Wolf, “The elusive memristor: properties of basic electrical circuits,” Eur. J. Phy., Vol. 30, pp. 661-675.
[16] J. Rajendran, H. Manem, R. Karri and G. S. Rose, “Approach to Tolerate Process Related Variations in Memristor-Based Applications,” Intl Conf on VLSI Design, pp. 18-23 (2011)
[17] H. Manem. J. Rajendran, and G. S. Rose, “Design Considerations for Multi-Level CMOS/Nano Memristive Memory,” ACM Journal of Emerging Technologies in Computing Systems, Vol. 8, No. 1, February 2012.
[18] G. S. Rose, Y. Yao, J. M. Tour, A. C. Cabe. N. Gergel-Hackett, N. Majumdar, J. C. Bean, L. R. Harriott, and M. R. Stan, “Designing CMOS/Molecular Memories while Considering Device Parameter Variations.” ACM Journal of Emerging Technologies in Computing Systems, Vol. 3, No. 1, April 2007.
[19] H. Manem and G. S. Rose. “A Read-Monitored Write Circuit for 1T1M Memristor Memories,” Proceedings of IEEE International Symposium on Circuits and Systems, Rio de Janeiro, Brazil. May 2011.
[20] M. Majzoobi. M. Rostami, F. Koushanfar. D. S. Wallach, and S. Devadas. “Slender PUF Protocol: A lightweight, robust, and secure authentication by substring matching,” in Proceedings of IEEE CS Security and Privacy Workshops. San Francisco, Calif., May 2012.

### BRIEF DESCRIPTION OF THE DRAWINGS

FIG. 1 depicts a 1-bit write-time based memristive PUF cell that leverages variations in memristor write times.

FIG. 2 depicts a change in resistance of a memristor with an applied voltage and the impact of process variations.

FIG. 3 depicts a timing diagram of sequence to setup write-time based memristive PUF and issue a challenge.

FIG. 4 depicts Monte Carlo simulation results showing the distribution in write-time given 2% variation in memristor thickness.

FIG. 5 depicts Monte Carlo simulation results showing the distribution in the output voltage of the write-time based memristive PUF given 2% variation in memristor thickness.

FIG. 6 depicts a schematic of one possible configuration of a write-time memristive PUF consisting of N memristive devices, an N-bit Challenge and an N-bit Response.

FIG. 7 depicts a schematic of one possible configuration of a write-time memristive PUF consisting of N memristive devices, an N-bit Challenge and an M-bit Response. This embodiment demonstrates XOR-mixing of M pairs of memristive PUF cells.

### DETAILED DESCRIPTION OF THE PREFERRED EMBODIMENT

Memristive devices or resistive RAM (ReRAM) are effectively two terminal electrical potentiometers. That is to say, memristive devices have tunable resistance values yet are non-volatile—do not require energy to persist at any resistance state. By applying the appropriate electrical bias for the required duration, the device may be repeatedly switched between at least two resistance states: a high resistance state (HRS) and a low resistance state (LRS). A SET operation switches the device from the HRS to the LRS; a RESET operation does the reverse. If the HRS is used to represent a logic ‘0’, then an LRS is a logic ‘1’.

There is no single memristor device design. Typically, these devices are as simple as metal-insulator-metal (MIM) structures, where the insulating layer has been constructed using such diverse material as chalcogenides [5, 6], metal oxides [7, 8], perovskites [9, 10], or organic films [11, 12]. Though the gambit of devices demonstrating the switching behaviors thus described may be understood to be “memristors” [11], the exact switching mechanism, parameters, and style is dependent upon the specific material stack.

The variations in device properties mean that certain flavors of memristive devices may be optimally suited for different applications. Typically, memristive devices considered for digital logic or memory applications are engineered for binary or multi-level states, where abrupt state transitions are desirable. Other devices demonstrate a more analog transition between the two extreme resistance states.

In the simplest analog model, memristors are modeled as two resistors, Rₒₙ as the LRS value and R_{off} as the HRS value, weighted by a factor α that varies between 0 and 1 over time. In short, the memristance may be written as

M(t)=α(t)Rₒₙ+(1−α(t))R_{off}

While the model is more complex in practice, the idea remains the same.

One method for fabricating memristors consists of placing a TiO_{2-X} layer with oxygen vacancies on a TiO₂ layer without oxygen vacancies and sandwiching them between metallic electrodes [12]. Though conical phase change regions were later shown to be responsible for device switching [13], this device can still be modeled as two series resistors (Rₒₙ and R_{off}) that represent doped and undoped regions of TiO_{X}, respectively. In the model, the thickness w of the active layer moves between 0 and the physical thickness D as a function of an applied electric field. In this way, the ratio of Rₒₙ and R_{off} of is described by α=w/D. Thus, the transition from the LRS to the HRS is an analog process.

[14, 15] expanded this model to account for variable mobility μ(t) as described by:

$$M ( t ) = {R}_{0} \sqrt{( 1 - \frac{2 ηΔ R ϕ ( t )}{{D}^{2} {R}_{0}^{2}} \cdot μ ( t ) {R}_{on} )} , \qquad ( 1 )$$

where constants R₀ is the maximum resistance (R₀≈R_{off}), ΔR is the difference between R_{off} and Rₒₙ, and η is the polarity (±1) of the applied voltage signal. The flux φ(t) is simply the integral of the applied voltage over the entire usage history of the device:

φ(t)=∫Vₐₚₚₗ(t)dt. (2)

Of particular importance to the write-time based memristive PUF is the impact of variations in parameters such as the device thickness D. More specifically, variability in D translates to variations in the read and write times of the memristor when using the device as a memory cell [16]. For example, a memristor being SET from HRS to LRS will only exhibit a logic ‘1’ output if the SET time is greater than some minimum t_{wr,min}. If, however, the SET time is chosen to be at or near the nominal t_{wr,min}, then variations in D will dictate if the output is nearly as likely to be a logic ‘0’ as it is a logic ‘1’. FIG. 2 shows the change in memristance for different values of D within the range of 2% variations from the nominal thickness Dₙₒₘ. This probabilistic status for the output voltage is undesirable for conventional memory systems but can be leveraged in the implementation of PUF circuits.

This variability in the write time of the device can be leveraged in the construction of the write-time based memristive PUF cell as depicted in FIG. 1 where the SET time t_{wr,set} (or RESET time t_{wr,reset}) is chosen to be the nominal minimum SET (RESET) time required to switch the memristor from the HRS (LRS) to the LRS (HRS) state, t_{wr,set,min} (t_{wr,reset,min}). If the actual SET (RESET) time of a particular memristor, t_{wr,set},act (t_{wr,reset,act}) is greater than t_{wr,set,min} (t_{wr,reset,min}), then the output voltage when reading the memory cell is likely a logic ‘0’ (logic ‘1’). Likewise, t_{wr,set,act} (t_{wr,reset,act}) less than t_{wr,set,min} (t_{wr,reset,min}) will likely lead to an output voltage of logic ‘1’ (logic ‘0’). By choosing the SET (RESET) time close to t_{wr,set,min} (t_{wr,reset,min}), the likelihood that the output is logic ‘1’ or logic ‘0’ should each be nearly 50%.

Given the memristor model described by equation (1) it is possible to estimate the nominal minimum SET time t_{wr,set,min} based on both device and circuit level parameters. For simplicity, the mobility μ(t)=μ is assumed to be constant such that the behavior follows the linear drift model for memristors presented in [15]. Furthermore, the SET operation consists of a long voltage pulse of magnitude Vₐₚₚₗ and duration t_{wr,set,min} such that φ(t)=φₘᵢₙ=Vₐₚₚₗ·t_{wr,set,min}. Substituting φₘᵢₙ into equation (1) and assuming the memristor is initially off (M(0)=R₀=R_{off}) one can obtain a relationship for the maximum resistance (R_{on,max}) that still yields a logic ‘1’ output:

$${R}_{on , max} = {R}_{0} \sqrt{( 1 - \frac{2 \cdot η \cdot Δ R \cdot {V}_{appl} \cdot {t}_{wr , set , min}}{{D}_{nom}^{2} \cdot {R}_{0}^{2}} \cdot μ \cdot {R}_{on} )} , \qquad ( 3 )$$

where Dₙₒₘ is the nominal thickness of the memristor. As is the case with t_{wr,set,min}, R_{on,max} represents the threshold between the off (or logic ‘0’) state and the on (or logic ‘1’) state for the memristor. Equation (3) can easily be solved to obtain an estimate of the nominal minimum SET time in terms of the device parameters and R_{on,max}:

$${t}_{wr , set , min} = [ 1 - {( \frac{{R}_{on , max}}{{R}_{0}} )}^{2} ] \cdot \frac{{D}_{nom}^{2} \cdot {R}_{0}^{2}}{2 \cdot η \cdot Δ R \cdot {V}_{appl} \cdot μ \cdot {R}_{on}} . \qquad ( 4 )$$

The term R_{on,max} is actually dependent on circuit parameters in that it represents the maximum resistance for which the circuit (e.g. comparator) interprets the memristor as being SET. For example, consider the circuit as shown in FIG. 1 where, during a read operation, the memristor is in series with a load resistor 109 R_{LD} and drives a comparator 110 at the point between the memristor and the load. The comparator can be defined as generating an output equivalent to a logic ‘1’ only if the input to the comparator is greater than a threshold Vₜₕ, otherwise a logic ‘0’ will be generated at the output. Thus, the value of the resistance R_{on,max} can be derived via a voltage divider where the voltage across the load R_{LD} is Vₜₕ:

$${R}_{on , max} = \frac{{V}_{RD}}{{V}_{th}} \cdot {R}_{LD} - {R}_{LD} . \qquad ( 5 )$$

Substituting equation (5) into equation (4) leads to the following relationship for the nominal minimum SET time in terms of the memristor device parameters and circuit parameters V_{RD}, Vₜₕ (comparator 110 threshold voltage) and R_{LD} (load resistance 109):

$${t}_{wr , set , min} = [ 1 - \frac{{( \frac{{V}_{RD}}{{V}_{th}} \cdot {R}_{LD} - {R}_{LD} )}^{2}}{{R}_{0}^{2}} ] \cdot \frac{{D}_{nom}^{2} \cdot {R}_{0}^{2}}{2 \cdot η \cdot Δ R \cdot {V}_{appl} \cdot μ \cdot {R}_{on}} \qquad ( 6 )$$

Referring to FIG. 1, the fundamental embodiment of the present invention comprises a CMOS-memristive circuit where a memristor 100 is written to a memristance state just on the edge between the states representing logic ‘1’ and logic ‘0’. In this particular situation, the actual state of the memristor 100 will yield either a logic ‘1’ or a logic ‘0’ because the variability of device parameters such as the thickness of the memristor dictate that the actual output is equally likely to be either a logic ‘1’ or ‘0’. Thus, the inherent process variations of memristive devices 100 are leveraged in the implementation of a PUF that can then provide a unique identifying signature for mitigating a variety of hardware security threats.

Still referring to FIG. 1, the fundamental embodiment of the invention is built upon a one-bit memristive memory cell consisting of the necessary logic to select whether the device is being written to or read from. Specifically, a read/write signal (R/W) 103 indicates whether the voltage across the memristor 100 is to be a high voltage write signal or a lower read voltage. In order to write the device toward either a logic ‘1’ or a logic ‘0’ state, a polarity signal (NEG) 104 is also used to appropriately reorient the polarity of the voltage drop across memristor 100. The analog output of the circuit when reading the state of the memristor 100 drives a sense amplifier or comparator 110 to convert the analog output value to a digital value. An XOR gate 111 is then used to provide the exclusive OR operation of the value read from the memristive memory and an applied Challenge 101. Finally, the output Response 102 of the XOR gates 111 in an array of such PUF cells is unique to the integrated circuit on which the circuit is implemented.

Still referring to the circuit shown in FIG. 1, the fundamental embodiment of the present invention comprises a single bit of the write-time based memristive PUF. The present invention is patentably distinguishable from the memristive memory presented in prior work [17-19]. Memristive memories require memristors oriented and connected in a two-dimensional configuration to facilitate access and reading of memory locations whereas in the present invention memristors are necessarily oriented in a one-dimensional configuration. Moreover, the control signal configuration and operation differ between memristive memories and memristive PUFs. In memristive PUFs like the present invention, the control signals are inputs and are manipulated to keep the memristors on the verge of state change. In contrast in memristive memories this would be avoided because it would yield unpredictable memory state. Furthermore, the presence of the exclusive OR gate in the present invention is not included in prior work and is necessary in a memristive PUF to combine user defined information (the Challenge) with hardware specific variability to provide the desired security.

Two control signals are used to determine whether the circuit is writing or reading the memristor ( R̅/W) 103 and, if writing, the polarity of the write (NEG) 104. These control signals are used to control the PUF by first initializing the memristor 100 to either the HRS (RESET first) or the LRS (SET first).

Referring to FIG. 3 depicts the waveform example of the RESET first case where the circuit works as a PUF by first performing a RESET of the memristor by applying NEG=1 and R̅/W=1 long enough to guarantee the memristor is in the HRS state. Next, a SET voltage pulse 105 is applied for the nominal write time corresponding to the t_{wr,set,min} (NEG=0 and R̅/W=1). After the SET operation, the memristor can be read at the output by applying R̅/W=0. The SET first case would operate in a similar fashion.

The Challenge signal 101 for this particular memristive PUF is applied as an input to an XOR gate 111 with the output of the memristive cell as the other input. The output of this XOR gate 111 is the Response bit 102 of the PUF cell which depends on the Challenge signal 101 and the random output of the memristive memory cell. When the likelihood that the output of the memristive memory cell is logic ‘1’ is 50%, then the chance that the Response bit 102 can correctly be guessed is equivalent to guessing the outcome of a coin flip. The Challenge signal is the “coded” aspect of the invention in that the user who understands the circuit function will know what Challenge bit(s) are required to produce a correct Response bit(s).

The variable mobility model has been included as a Verilog-A model for circuit simulations using Tanner EDA T-Spice. For the device modeled. Rₒₙ, is 121 kΩ, R_{off} is 121MΩ, D is nominally 50 nm, μ₀ is 3×10⁻¹⁸ m²/V·s, and E₀˜25 MV/m. Note that for an operating voltage less than ±+0.2V (threshold voltage for D=50 nm and E₀˜25 MV/m), the memristor 100 follows the linear drift model; and the device memristance does not alter much with respect to time (almost constant). So in the read mode, when the circuit is being used with an operating voltage˜1V, the memristance is essentially constant. During the write mode, where the memristance is SET or RESET, programming voltages greater than 1.2V must be used.

For the RESET first case, one way to determine the nominal t_{wr,set,min} is by running Monte Carlo simulations and producing a histogram of the minimum SET time to SET the TiOₓ memristor modeled earlier. FIG. 4 shows the distribution of the SET time for 2% variation in thickness. The write voltage for the results in FIG. 4 is 1.5 V. From each of these plots, it is clear that the expected minimum SET time for the circuit in FIG. 1 is around 7 μs. The Monte Carlo simulations were run for 1,000 iterations for each variation parameter considered.

Referring to FIG. 5 shows the distributions of the output of a read operation to the memory cell initialized to the HRS but SET to the LRS by applying a 7 μs write pulse. The results illustrated in FIG. 5 are for a device allowing for up to 2% variation in thickness. As was done for the write time distributions, Monte Carlo simulations were run for 1,000 iterations using T-Spice. It is clear from FIG. 5 that the likelihood that the output is logic ‘0’ is close to that of logic ‘1’, though it appears a logic ‘0’ is slightly more likely. It can also be seen that as the variation in thickness increases the likelihood for a logic ‘1’ is improved over that of logic ‘0’.

There are several ways in which the write-time based memristive PUF cell can be used to construct a PUF with a multi-bit Challenge 101 and a multi-bit Response 102. One straightforward embodiment of an N-bit memristive PUF is illustrated in FIG. 6, consisting of N memristive devices 100, N Challenge bits 201 and N Response bits 202. Here, each column in the PUF consists of one memristive PUF cell like that illustrated in FIG. 1. Of note in FIG. 6 is that much of the selection circuitry can be shared amongst all PUF cells. The one selection circuit that must be implemented for each memristive PUF cell is the output side R/W selection circuit 107. In FIG. 6, the output side R/W selection circuits are implemented with two pass transistors 203 per memristive PUF cell and one shared inverter 204, showing a reasonable transistor level implementation of the multiplexers used for the selection circuitry.

Referring to FIG. 7 depicts another embodiment of a multi-bit write-time based PUF. This circuit is very similar to that of FIG. 6 with the exception that the M Response bits 202 are generated by taking the XOR of the outputs of pairs of memristive PUF cells via a second stage of XOR gates 205. As done for other PUF architectures [20], this XOR-mixed arrangement could help improve statistical properties of the PUF.

What is claimed is:

1. A write-time based memristive physical unclonable function apparatus, comprising:
a memristor having a first terminal and a second terminal;
a first read/write selection circuit having a first input connected to a read signal line, a second input connected to an output of a first orientation selection circuit, a control input connected to a read/write control signal, and an output connected to said first terminal of said memristor;
a first orientation selection circuit having a first input connected to a write signal line, a second input connected to ground, a control input connected to a set/reset control signal, and an output connected to said second input of said first read/write selection circuit;
a second read/write selection circuit having a first input connected to an output of a second orientation selection circuit, a second input connected to a first terminal of a load resistor having a first and a second terminal, a control input connected to a read/write control signal, and an output connected to said first terminal of said memristor;
a second orientation selection circuit having a first input connected to a write signal line, a second input connected to ground, a control input connected to a set/reset control signal, and an output connected to said first input of said second read/write selection circuit;
a comparator having an input terminal and an output terminal, wherein said input terminal is connected to said first terminal of said load resistor and said second input of said second read/write selection circuit;
a XOR gate having a first input, a second input and an output wherein said first input connected to said output terminal of said comparator, said second input is connected to a challenge signal, and said output generates a response signal; and
wherein said second terminal of said load resistor is connected to ground.

2. The write-time based memristive physical unclonable function apparatus of claim 1, wherein a random response state is generated by
pulling said read/write control signal high and said pulling set/reset control signal high will reset said memristor to a known state;
pulling said set/reset control signal low for the minimal amount of time to cause said memristor to change from a high resistance state to a low resistance state while leaving said read/write control signal high, wherein said minimal amount of time is determined by empirical measurement of said memristor;
pulling said read/write control signal low so as to read the state of said memristor;
setting said challenge signal to either a logical “1” or “0” state as defined by the user, while still reading the state of said memristor, and determining the logic state of said response signal.

3. The write-time based memristive physical unclonable function apparatus of claim 1, wherein a random response state is further generated by
pulling said read/write control signal high and said pulling set/reset control signal low will set said memristor to a known state;
pulling said set/reset control signal high for the minimal amount of time to cause said memristor to change from a low resistance state to a high resistance state while leaving said read/write control signal high, wherein said minimal amount of time is determined by empirical measurement of said memristor;
pulling said read/write control signal low so as to read the state of said memristor;
setting said challenge signal to either a logical “1” or “0” state as defined by the user, while still reading the state of said memristor, and determining the logic state of said response signal.

4. A write-time based memristive physical unclonable function apparatus, comprising:
a memristor having a first and a second terminal;
a first set of control circuitry connected to said first terminal of said memristor functioning in cooperation with a second set of control circuitry connected to said second terminal of said memristor to facilitate the setting, resetting, writing and reading of said memristor, wherein said first and said second set of control circuitry is responsive to external control signals; and
a set of logic circuitry having as an input, an output of said second set of control circuitry, wherein said set of logic circuitry randomly produces a logical “1” or logical “0” as an output upon the non-random application of said external control signals.

5. Said write-time based memristive physical unclonable function apparatus of claim 4 wherein said non-random application of said external control signals further comprises applying a control signal of a minimum duration necessary to cause said memristor to change resistance state either from a low to high resistance state or from high to low resistance state; wherein said minimal duration is determined by empirical measurement of said memristor.

6. A multi-bit write-time based memristive physical unclonable function apparatus, comprising:
a plurality of memristors each having a first and a second terminal;
a first set of control circuitry connected to said first terminal of each of said plurality of memristors functioning in cooperation with a second set of control circuitry connected to said second terminal of each of said memristors to facilitate the setting, resetting, writing and reading of said memristor, wherein said first and said second set of control circuitry is responsive to external control signals; wherein said second set of control circuitry further comprises a number of outputs corresponding to a number of said bits;
a plurality of logic circuits each having as an input one output of said second set of control circuitry, wherein each of said plurality of logic circuits randomly produces a logical “1” or logical “0” as an output upon the non-random application of said external control signals.

7. The multi-bit write-time based memristive physical unclonable function apparatus of claim 6, further comprising
exclusive OR logic gates into which said logic circuit outputs are paired as inputs, wherein said exclusive OR logic gates each randomly produce as outputs a logical “1” or logical “0” with improved statistical properties.

8. The write-time based memristive physical unclonable function apparatus of claim 1 wherein said second read/write selection circuit comprises two pass transistors.

9. Said write-time based memristive physical unclonable function apparatus of claims 2, 3, and 5 wherein said minimal amount of time is defined by the expression
$${t}_{wr , set , min} = [ 1 - \frac{{( \frac{{V}_{RD}}{{V}_{th}} \cdot {R}_{LD} - {R}_{LD} )}^{2}}{{R}_{0}^{2}} ] \cdot \frac{{D}_{nom}^{2} \cdot {R}_{0}^{2}}{2 \cdot η \cdot Δ R \cdot {V}_{appl} \cdot μ \cdot {R}_{on}} .$$
where
t_{wr,set,min} is the duration of Vₐₚₚₗ;
Vₐₚₚₗ is long voltage pulse of magnitude V;
R_{LD} is the resistance of said load resistor;
Vₜₕ is a comparator threshold voltage;
V_{RD} is a voltage applied to read the state of said memristor;
Dₙₒₘ is a memristor nominal thickness;
μ is a mobility constant;
Rₒₙ is a memristor low resistance value;
ΔR is the difference between R_{off} and Rₒₙ;
R_{off} is a memristor high resistance value;
η is the polarity (+1) of an applied voltage signal; and
R₀ is a memristor maximum resistance.
